(19) United States
(12) Patent Application Publication
(10) Pub. No.: US 2011/0204444 A1
(43) Pub. Date: Aug. 25, 2011

(54) Semiconductor intergrated device and method of manufacturing same

(75) Inventor: Masao Okihara, Miyagi (JP)

(73) Assignee: OKI SEMICONDUCTOR CO., LTD., Tokyo (JP)

(21) Appl. No.: 12/929,820

(22) Filed: Feb. 17, 2011

(30) Foreign Application Priority Data
Feb. 23, 2010 (JP) 2010-037626

(51) Int. Cl. H01L 29/786; H01L 21/84; H01L 27/12

(52) U.S. Cl. 257/347; 438/151; 257/506; 257/E29.295; 257/E21.704; 257/E27.112

(57) ABSTRACT

A semiconductor integrated device of the invention can enhance a radiation resistance. In an exemplary embodiment, the semiconductor integrated device includes a semiconductor supporting substrate, an insulation layer provided on the semiconductor supporting substrate, and a silicon thin film provided on the insulation layer. A predetermined region in the silicon thin film that is adjacent to the boundary between the insulation layer and the silicon thin film (i.e., boundary neighboring region) has an impurity-concentration-increased region. In this region, the impurity concentration becomes higher as the position approaches the boundary.

### BACKGROUND OF THE INVENTION

The present invention generally relates to a semiconductor integrated device, and more particularly to a semiconductor integrated device having a CMOS (Complementary Metal Oxide Semiconductor) structure with an SOI (Silicon On Insulator) substrate. The present invention also relates to a method of manufacturing such semiconductor device.

### SUMMARY OF THE INVENTION

In recent years, a semiconductor integrated device having a CMOS structure with a silicon substrate (may be referred to as “Si substrate”) is often used in a personal communication equipment and a mobile communication equipment.

More integration is demanded for fine structure in the field of semiconductor device. Also, there is a demand for faster speed in calculation and operation. These tendencies, however, entail increased power consumption. To meet these demands, a new device configuration with a new element structure is desired. One answer to these demands is a semiconductor integrated device having a CMOS structure with an SOI substrate (referred to as “SOI device”). This semiconductor integrated device consumes less electricity and possesses enhanced performances. The SOI substrate has an insulation layer between a silicon substrate and a silicon film (referred to as “SOI layer”). For example, see Japanese Patent Application Publication (Kokai) No. 2009-183714 (particularly, FIG. 8A to FIG. 8C and paragraph 0032 to paragraph 0033 of this Japanese publication).

Since the SOI device has a buried (embedded) oxide film (referred to as “BOX”) under the SOI layer, the parasitic capacitance at the source-drain becomes smaller, and therefore the SOI device can operate at higher speed and consumes less electricity. In addition, the BOX completely separates the respective elements from each other, and therefore a latch-up problem would not arise. This enables a high-density layout. BOX means buried oxide.

One of SOI devices having an excellent radiation-resistance that can be used in space and in X-ray-radiated environment is an FD-SOI device. FD stands for fully depleted. The FD-SOI device is able to operate properly even when a channel region is completely depleted. The thickness of the silicon film in the FD-SOI device that functions as the component is thin. Thus, a less amount of pairs of electrons and holes is produced in the silicon upon radiation of X-rays. In other words, the FD-SOI device has an enhanced radiation-resistance.

It is known that the oxide film of the BOX under the SOI layer in the FD-SOI device assumes a trap state because of radiation-caused damages. Generally the trap state in the oxide film is a state (level) to capture positive electric-charge. Accordingly, when radiation-caused damages are significant and an amount of trap generated thereupon is large, then it appears that a positive bias is applied to the back face of the SOI layer. Because the channel impurities of the FD-SOI device are implanted by an ion implantation technique, there is created a profile that the upper portion of the SOI layer has a higher impurity density than the lower portion of the SOI layer. The channel impurity density is low(er) in the lower portion of the SOI layer, and therefore polarity reversing tends to occur in the lower portion of the SOI layer. This results in so-called “back channel” and in turn causes current leakage.

As understood from the foregoing, if the FD-SOI device is subjected to the radiation-caused damages, the back channel is created in the back face of the SOI layer and a leakage current flows through the back channel. This leakage current causes the malfunctioning of the device.

One object of the present invention is to provide a semiconductor integrated device that has an increased radiation-resistance.

Another object of the present invention is to provide a method of making such semiconductor integrated device.

According to a first aspect of the present invention, there is provided a semiconductor integrated device that includes a semiconductor supporting substrate, an insulation layer provided on the semiconductor supporting substrate, and a silicon thin film provided on the insulation layer. A predetermined region in the silicon thin film that is adjacent to the boundary between the insulation layer and the silicon thin film (i.e., boundary neighboring region) has an increased impurity concentration. The impurity concentration in a particular part of this region becomes higher as the concentration measuring position approaches the boundary between the insulation layer and the silicon thin film.

The silicon thin film is provided on the insulation layer, and the silicon thin film has the impurity-density-increased region in its lower part. The impurity density has a peak in the impurity concentration increased region. This brings about the following advantage. Even if a trap level arises in the insulation layer because of considerable damages upon radiation, polarity inversion is unlikely to occur in the lower part of the silicon thin film. In other words, malfunctioning of the device is prevented even if there is a significant damage due to radiation.

According to a second aspect of the present invention, there is provided a method of making a semiconductor integrated device. The semiconductor integrated device includes a semiconductor supporting substrate, an insulation layer provided on the semiconductor supporting substrate, and a silicon thin film provided on the insulation layer. The method includes the step of providing the insulation layer on the semiconductor supporting substrate, and providing the silicon thin film on the insulation layer. The method also includes the step of ion implanting an impurity (or impurities) into the silicon thin film to control a transistor threshold. This step may be referred to as a first ion implantation step. The method also includes the step of ion implanting additional impurity (or impurities) into the silicon thin film such that the lower area of the silicon thin film has a higher impurity density than the upper area of the silicon thin film. This step may be referred to as a second ion implantation step.

The silicon thin film is provided on the insulation layer, and the silicon thin film has an impurity-density increased region in the lower part of the silicon thin film. Therefore, even if a trap level arises in the insulation layer because of considerable radiation-caused damages, polarity inversion is unlikely to occur in the lower part of the silicon thin film. In other words, malfunctioning of the device is prevented even if there is a significant damage due to radiation.

The method of manufacturing the semiconductor integrated device may further include a leveling step before the second ion implantation step to level the impurity concentration in the silicon thin film.

These and other objects, aspects and advantages of the present invention will become apparent to those skilled in the art when the following detailed description is read and understood in conjunction with the appended claims and drawings.

### BRIEF DESCRIPTION OF THE DRAWINGS

FIG. 1 illustrates a cross-sectional view of an SOI device, which is a semiconductor integrated device, according to an embodiment of the present invention;

FIG. 2 is a diagram that shows an impurity density profile in a depth direction of a channel region of the SOI device according to the first embodiment at the present invention.

FIG. 3A is a cross-sectional view showing a first step in a process of making an SOI device according to the first embodiment of the present invention;

FIG. 3B is a cross-sectional view at a second step (or first ion implantation) in the process of making the SOI device according to the first embodiment of the present invention;

FIG. 3C is a cross-sectional view at a third step (or second ion implantation) in the process of making the SOI device according to the first embodiment of the present invention;

FIG. 3D is a cross-sectional view at a fourth step in the process of making the SOI device according to the first embodiment of the present invention;

FIG. 3E is a cross-sectional view at a fifth step in the process of making the SOI device according to the first embodiment of the present invention;

FIG. 4 illustrates an impurity density profile in the channel region of the SOI device prior to the second ion implantation;

FIG. 5A is a cross-sectional view at a first step in a process of making an SOI device according to a second embodiment of the present invention;

FIG. 5B is a cross-sectional view at a second step (or first ion implantation) in the process of making the SOI device according to the second embodiment of the present invention;

FIG. 5C is a cross-sectional view at a third step (or impurity density leveling) in the process of making the SOI device according to the second embodiment of the present invention;

FIG. 5D is a cross-sectional view at a fourth step in the process of making the SOI device according to the second embodiment of the present invention;

FIG. 5E is a cross-sectional view at a fifth step in the process of making the SOI device according to the second embodiment of the present invention;

FIG. 5F is a cross-sectional view at a sixth step in the process of making the SOI device according to the second embodiment of the present invention; and

FIG. 6 illustrates an impurity density profile in a depth direction of a channel region of the SOI device according to the second embodiment of the present invention.

### DETAILED DESCRIPTION OF THE INVENTION

Exemplary embodiments of the present invention will now be described in detail with reference to the accompanying drawings.

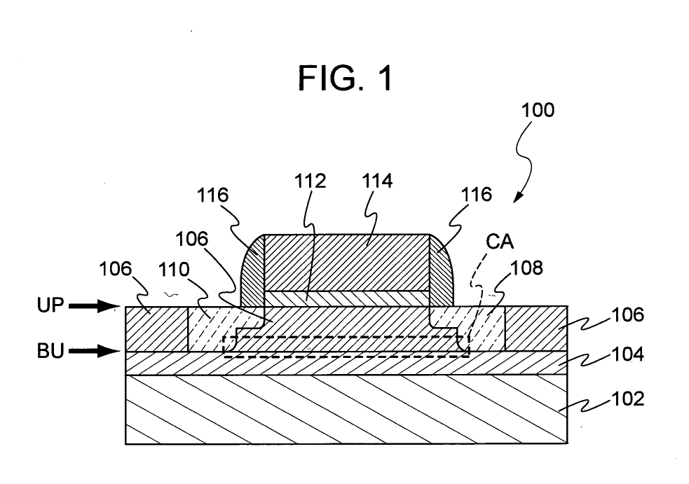

An SOI device having an FD-SOI structure 100 will be described with FIG. 1. This SOI device 100 is a semiconductor integrated device according to an embodiment of the present invention.

The SOI device 100 includes a silicon substrate 102, a

BOX layer 104, and an SOI layer 106. The silicon substrate 102, BOX layer 104 and SOI layer 106 are stacked to provide an SOI substrate. The silicon substrate 102 is a silicon support substrate. The BOX layer 104 is an insulation layer. The SOI layer 106 is a silicon thin-film. The SOI layer 106 has a source region 108 and a drain region 110. A lower face of the source region 108 and a lower face of the drain region 110 are in contact with the BOX layer 104. A gate insulation layer 112 is provided on the SOI layer 106, and a gate electrode 114 is provided on the gate insulation film 112. A side wall 116 is provided along the side faces of the gate electrode 114. A transistor channel region is formed in the SOI layer 106 between the source region 108 and drain region 110 under the gate insulation film 112.

In FIG. 1, a BOX boundary BU is defined between the BOX layer 104 and SOI layer 106, and a BOX boundary neighboring region CA is defined in the channel region of the SOI layer 106 in the vicinity of the BOX boundary BU. The BOX boundary neighboring region CA is indicated by the chain-line rectangle. The density (concentration) of the impurity or impurities introduced by the ion implantation becomes higher in the BOX boundary neighboring region CA as the location is closer to the boundary BU.

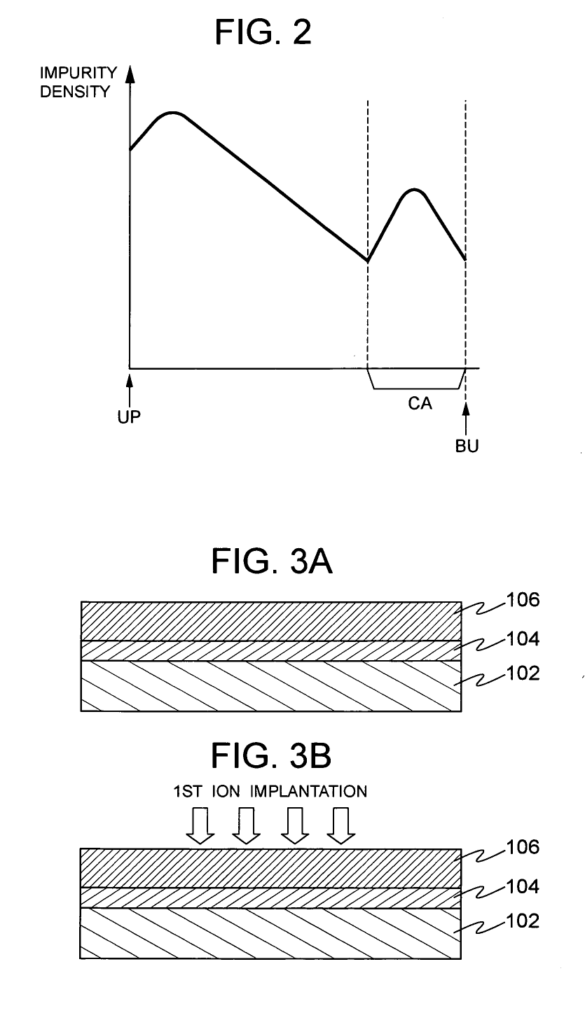

FIG. 2 shows an impurity density (concentration) profile in the channel region in the depth direction toward the boundary BU from the upper face UP of the SOI layer 106 of FIG. 1.

As depicted in FIG. 2, the impurity concentration in the channel region of the SOI layer 106 reaches the peak value near the upper face UP of the SOI layer 106, and decreases toward the boundary BU. It should be noted, however, that the impurity concentration curve has a second peak in the area CA of the SOI layer 106, as shown in FIG. 2. In other words, the impurity concentration increases before the boundary BU in the BOX boundary neighboring area CA and decreases again.

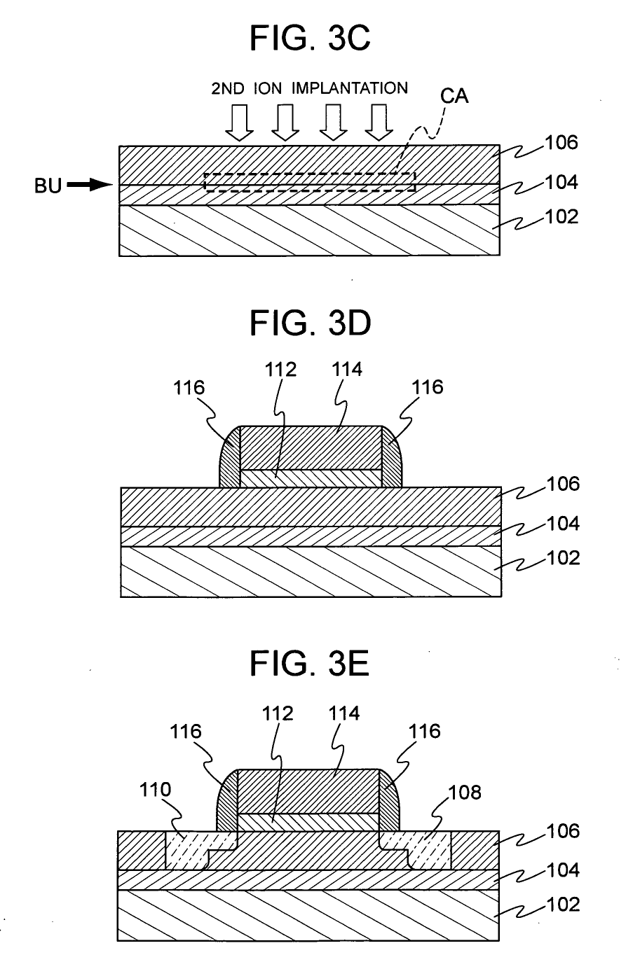

Now, a method of manufacturing the SOI device 100 will be described with reference to FIG. 3A to FIG. 3E. Each of FIG. 3A to FIG. 3E is a cross-sectional view of the SOI device at the respective steps in the manufacturing method.

Referring to FIG. 3A, the SOI substrate is prepared by a known process such as unibond process or SIMOX (separation by implanted oxygen) process. The BOX layer 104 (i.e., insulation layer) is provided on the silicon substrate 102 (i.e., silicon support substrate). The SOI layer (i.e., silicon layer) 106 is provided on the BOX layer 104.

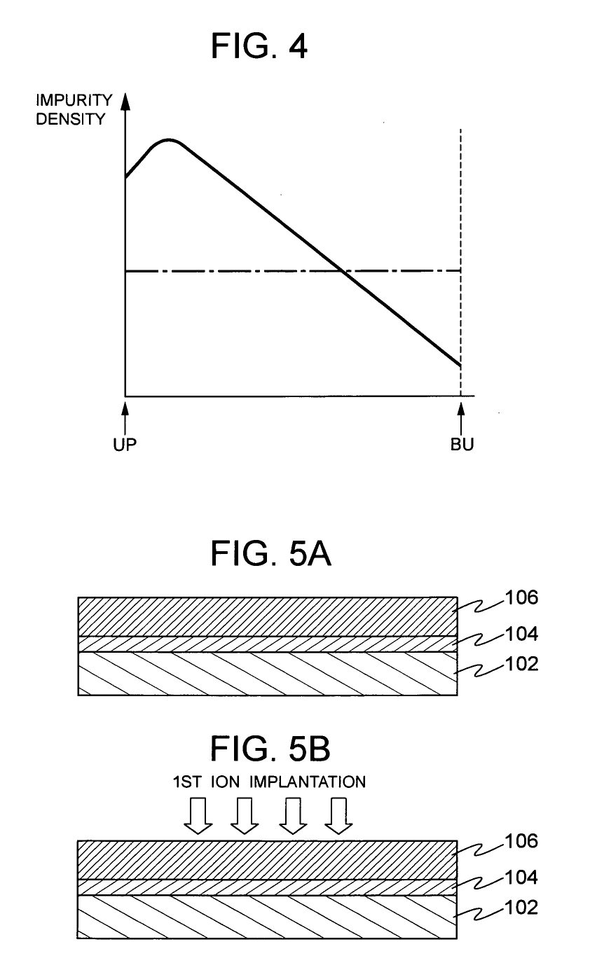

Referring to FIG. 3B, a certain amount of impurity (or impurities) is implanted into the SOI layer 106 to control a transistor threshold value. This ion implantation is a first ion implantation. The first ion implantation is carried out such that the impurity concentration of the SOI layer 106 takes a profile (solid line) shown in FIG. 4. This profile has a peak near the SOI upper face UP, and decreases to the boundary BU.

Referring to FIG. 3C, another ion implantation (i.e., second ion implantation) is carried out to implant the impurity (or impurities) into the SOI layer 106 such that the additional impurities are more implanted in a lower portion of the SOI layer 106 than in an upper portion of the SOI layer 106. The second ion implantation targets the BOX boundary neighboring area CA of the SOI layer 106, and introduces an additional ion to increase the impurity concentration in the target area CA. As a result, the concentration of the total impurities implanted into the SOI layer 106 takes the profile shown in FIG. 2. As described earlier, the impurity concentration profile has a peak value near the upper face UP of the SOI layer 106, and decreases until the area CA when the impurity concentration profile is observed from the top surface UP to the boundary BU. The impurity concentration profile then has another peak in the BOX boundary neighboring area CA, and decreases until the boundary BU.

Referring to FIG. 3D, the gate insulation film 112 is provided on the SOI layer 106. The gate insulation film 112 is the silicon oxide film. The gate electrode 114 is provided on the gate insulation film 112. The gate electrode 114 is the polysilicon. The sidewall 116 is provided along the lateral face of the gate electrode 114.

Referring to FIG. 3E, another ion implantation is carried out near the side wall 116 such that the ion is implanted in the upper face of the SOI layer 106. A heat treatment is subsequently carried out such that the source region 108 and drain region 110 are created. Consequently, the SOI device 100 shown in FIG. 1 is obtained.

As described above, the BOX boundary neighboring area CA in the channel region of the SOI layer 106 is the target area of the SOI device 100 for second ion implantation. The impurity concentration in the BOX boundary neighboring area CA is thus increased. As a result, even if a trap potential (trap level) arises in the BOX layer 104 upon considerable damages by radiation, the polarity inversion hardly occurs (or does not occur at all) in the lower face of the SOI layer 106. In other words, even if a significant damage occurs upon radiation, the malfunctioning of the device 100 does not occur. The upper face of the SOI layer 106 is not affected by the second ion implantation into the BOX boundary neighboring area CA of the SOI layer 106 (i.e., not affected by the increased impurity concentration). Therefore, the SOI device 100 continues to function properly while providing its transistor with an increased radiation-resistance.

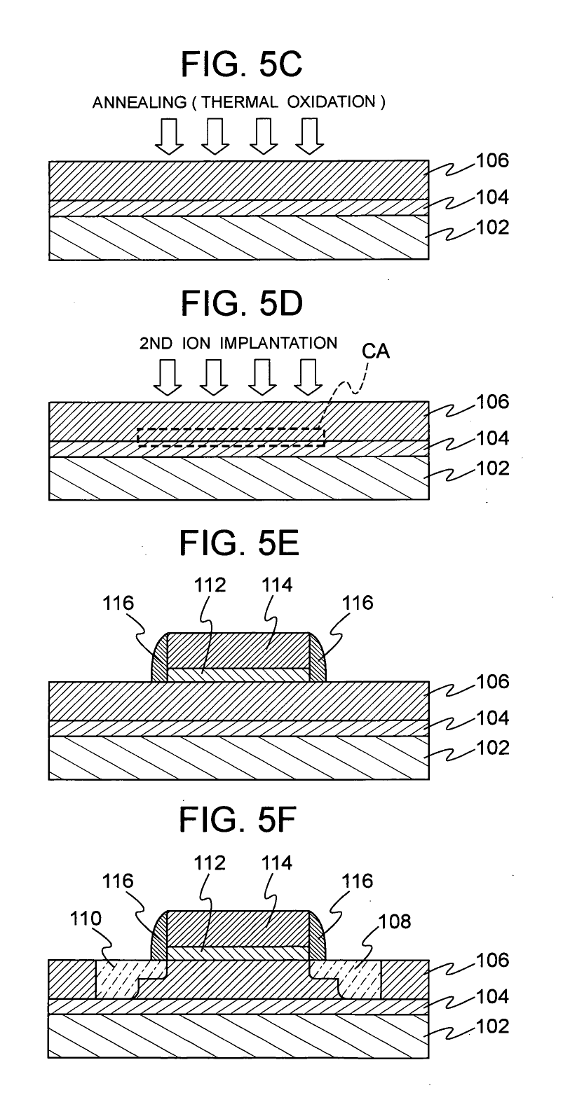

It should be noted that when manufacturing the SOI device 100 shown in FIG. 1, the process depicted in FIG. 5A to FIG. 5F may be used instead of the process depicted in FIG. 3A to FIG. 3E.

First, as illustrated in FIG. 5A, the SOI substrate is prepared by a known technique such as unibonding or SIMOX process. The BOX layer 104 is formed on the silicon substrate 102. The BOX layer 104 is an insulation layer. The silicon substrate 102 is a silicon supporting substrate. The SOI layer 106 is formed on the BOX layer 104. The SOI layer 106 is a silicon layer.

Then, as illustrated in FIG. 5B, an impurity is implanted to the SOI layer 106 to control (or adjust) the transistor threshold. This is the first ion implantation. The impurity concentration in the SOI layer 106 has a profile as shown in FIG. 4 (solid-line curve in FIG. 4). Specifically, the impurity concentration profile or curve has a peak near the upper face UP of the SOI layer 106, and the impurity concentration value decreases toward the boundary BU.

As shown in FIG. 5C, the annealing or thermal-oxidation is applied to the SOI layer 106 for the leveling of the impurity concentration in the SOI layer 106. This process may be referred to as impurity concentration leveling. As a result of this process, the impurity concentration profile of the SOI layer 106 becomes flat from the upper face UP to the boundary BU of the SOI layer 106, as indicated by the chain-line in FIG. 4.

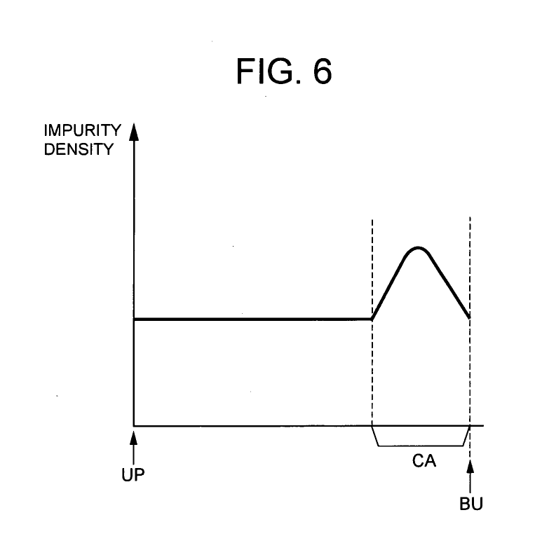

As shown in FIG. 5D, another ion implantation is carried out to the SOI layer 106 such that the impurity concentration in the lower portion of the SOI layer 106 is increased relative to the upper portion of the SOI layer. This is the second ion implantation. The target area of the second ion implantation is the BOX boundary neighboring area CA of the SOI layer 106. As a result of the second ion implantation, the impurity concentration in the target area CA is increased. Specifically, the impurity concentration in the SOI layer 106 takes a profile shown in FIG. 6. The impurity concentration increases, reaches a peak and decreases in the BOX boundary neighboring area CA. The impurity concentration decreases toward the boundary BU from the peak. The impurity concentration in the SOI layer 16 except for the BOX boundary neighboring area CA is constant, and its value is smaller than the value in the BOX boundary neighboring area CA.

As shown in FIG. 5E, the gate insulation film 112 is formed on the SOI layer 106. The gate insulation film 112 is a silicon oxide film. The gate electrode 114 is formed on the gate insulation film 112. The gate electrode 114 is made from polysilicon. The sidewall 116 is formed along on the lateral face of the gate electrode 114.

In the vicinity of the sidewall 116, the upper face of the SOI layer 106 is ion implanted. Subsequently, the SOI layer 106 undergoes heat treatment to create the source region 108 and drain region 110, as shown in FIG. 5F. Accordingly the SOI device 100 of FIG. 1 is obtained.

As understood from the foregoing, the manufacturing method depicted in FIG. 5A to FIG. 5F performs the first ion implantation for implanting the impurity (or impurities) to the SOI layer 106 to control the transistor threshold and then performs the impurity concentration leveling step for leveling the impurity concentration in the SOI layer 106 prior to the second ion implantation. The second ion implantation is performed to increase the impurity concentration in the BOX boundary neighboring area CA of the SOI layer 106. Therefore, the impurity concentration in the channel region of the resulting SOI device 100 has an increased value (or becomes higher) in the BOX boundary neighboring area CA of the SOI layer 106, as shown in FIG. 6.

This is particularly advantageous because no (or only small) polarity reversal occurs in the lower portion of the SOI layer 106 even when a trap potential (level) arises in the BOX layer 104 due to radiation-caused damages. This prevents the malfunctioning of the SOI device 100.

This application is based on Japanese Patent Application No. 2010-37626 filed on Feb. 23, 2010 and the entire disclosure thereof is incorporated herein by reference.

What is claimed is:

1. A semiconductor integrated device comprising:
a semiconductor supporting substrate;
an insulation layer provided on the semiconductor supporting substrate;
a silicon thin film provided on the insulation layer; and
an impurity concentration-increased region formed in the silicon thin film, wherein the impurity concentration-increased region extends adjacent to a boundary between the insulation layer and the silicon thin film, and an impurity concentration becomes higher in a predetermined part of the impurity concentration-increased region as a concentration measuring position approaches said boundary.

2. The semiconductor integrated device of claim 1, wherein the silicon thin film has a drain region and a source region, and the impurity concentration-increased region is located in a channel region between the drain region and source region in the silicon thin film.

3. The semiconductor integrated device of claim 1, wherein the semiconductor supporting substrate is a silicon substrate.

4. The semiconductor integrated device of claim 1, wherein the insulating layer is a BOX layer.

5. The semiconductor integrated device of claim 1, wherein the silicon thin film is an SOI layer.

6. The semiconductor integrated device of claim 1, wherein the impurity concentration has a peak value in the impurity concentration-increased region.

7. The semiconductor integrated device of claim 6, wherein the impurity concentration in the silicon thin film has another peak value outside the impurity concentration-increased region.

8. The semiconductor integrated device of claim 1, wherein the impurity concentration is constant outside the impurity concentration-increased region.

9. The semiconductor integrated device of claim 6, wherein the impurity concentration is constant outside the impurity concentration-increased region.

10. A method of making a semiconductor integrated device comprising:
preparing a semiconductor supporting substrate;
providing an insulation layer on the semiconductor supporting substrate;
providing a silicon thin film on the insulation layer;
ion implanting impurities into the silicon thin film to control a transistor threshold; and
ion implanting additional impurities into the silicon thin film such that the additional impurities are more implanted in a lower area of the silicon thin film than in an upper area of the silicon thin film.

11. The method of claim 10 further including leveling the impurity concentration in the silicon thin film, between said ion implanting impurities and said ion implanting additional impurities.

12. The method of claim 11, wherein said leveling the impurity concentration includes annealing the silicon thin film.

13. The method of claim 11 wherein said leveling the impurity concentration includes applying thermal oxidation to the silicon thin film.

14. The method of claim 10 further comprising forming a gate insulating film on the silicon thin film, forming a gate electrode on the gate insulating film, and forming a sidewall around the gate electrode.

15. The method of claim 14 further comprising applying ion implantation to the silicon thin film and applying heat treatment to the silicon thin film to form a source region and drain region.

16. The method of claim 10, wherein said ion implanting additional impurities is carried out such that the impurity concentration has a peak value in the lower area of the silicon thin film.

17. The method of claim 11, wherein the impurity concentration in the silicon thin film after said ion implanting additional impurities has a peak value in the lower area of the silicon thin film and has a constant value outside the lower area of the silicon thin film.

18. A semiconductor integrated device comprising:
a semiconductor supporting substrate;
an insulation layer provided on the semiconductor supporting substrate;
a silicon thin film provided on the insulation layer; and
a radiation-resistance-increased region formed in the silicon thin film, wherein the radiation-resistance-increased region extends adjacent to a boundary between the insulation layer and the silicon thin film.
